(19) United States
(12) Patent Application Publication
(10) Pub. No.: US 2025/0220992 A1
(43) Pub. Date: Jul. 3, 2025

(54) INTEGRATED CIRCUIT DEVICE AND MANUFACTURING METHOD THEREOF

(71) Applicant: TAIWAN SEMICONDUCTOR MANUFACTURING COMPANY, LTD., Hsinchu (TW)

(72) Inventors: Chun-Yuan CHEN, Hsinchu (TW); Sheng-Tsung WANG, Hsinchu (TW); Huan-Chieh SU, Changhua County (TW); Kuo-Cheng CHIANG, Hsinchu County (TW); Chih-Hao WANG, Hsinchu County (TW)

(73) Assignee: TAIWAN SEMICONDUCTOR MANUFACTURING COMPANY, LTD., Hsinchu (TW)

(21) Appl. No.: 18/402,976

(22) Filed: Jan. 3, 2024

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/017; H10D 64/018

(57) ABSTRACT

A method for manufacturing an integrated circuit device is provided. The method includes depositing an epitaxial stack over a semiconductor substrate, wherein the epitaxial stack comprises a plurality of first and second semiconductor layers alternatively arranged over the semiconductor substrate and a third semiconductor layer over the first and second semiconductor layers; patterning the epitaxial stack to form a semiconductor fin; forming a dummy gate structure over the semiconductor fin; replacing the third semiconductor layer in the semiconductor fin with a dielectric layer; and replacing the dummy gate structure and first semiconductor layers in the semiconductor fin with a metal gate structure.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET), including a gate-all-around (GAA) FET. In a GAA FET, all side surfaces of the channel region are surrounded by the gate electrode, which allows for fuller depletion in the channel region and results in less short-channel effects due to steeper sub-threshold current swing (SS) and smaller drain induced barrier lowering (DIBL).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17 illustrate a method of manufacturing an integrated circuit device at various stages in accordance with some embodiments.

FIG. 18 is a cross-sectional view of an integrated circuit device at various stages in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

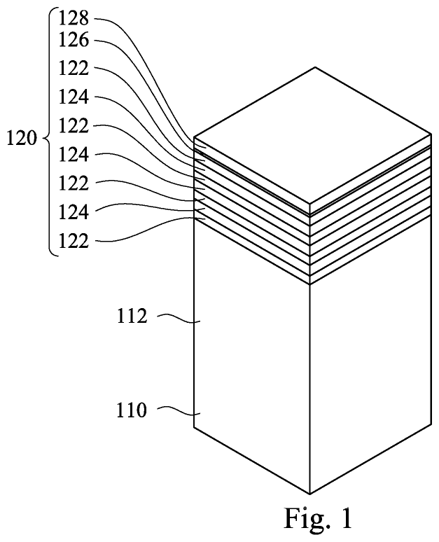

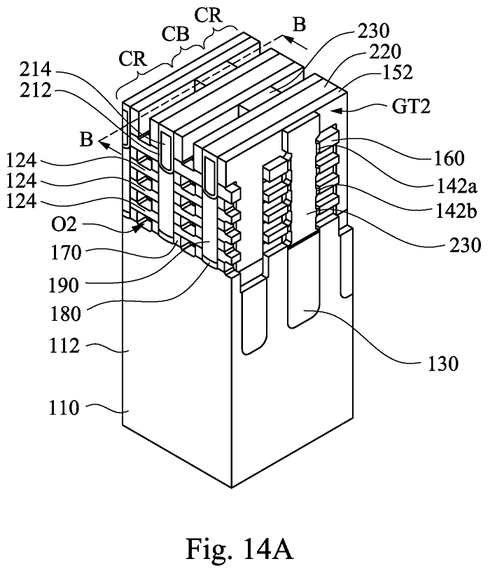

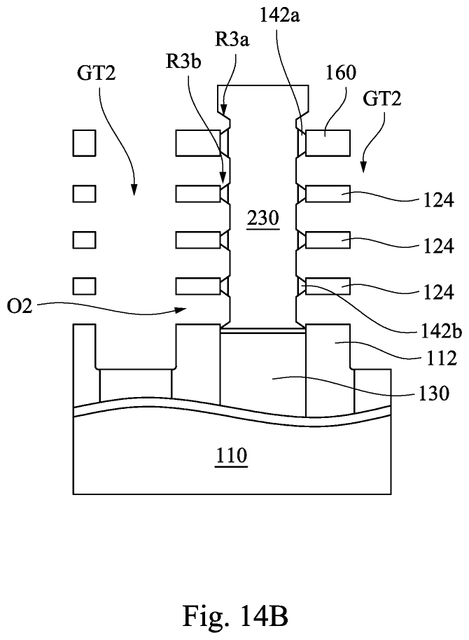

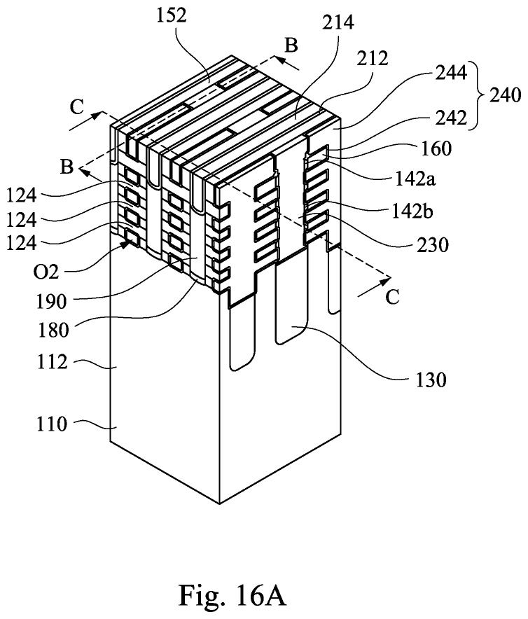

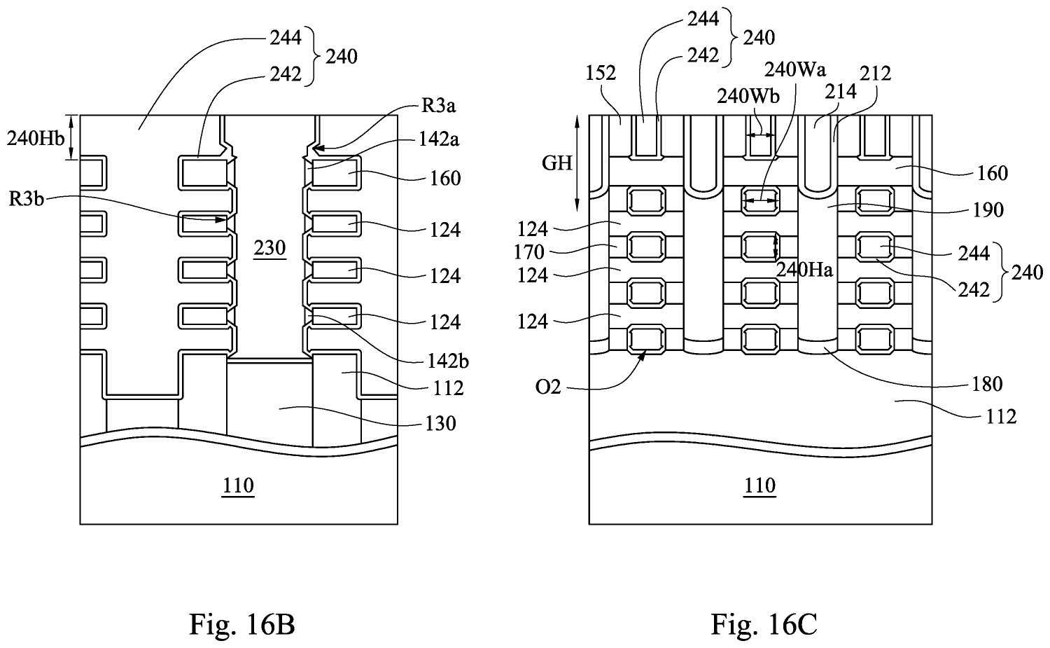

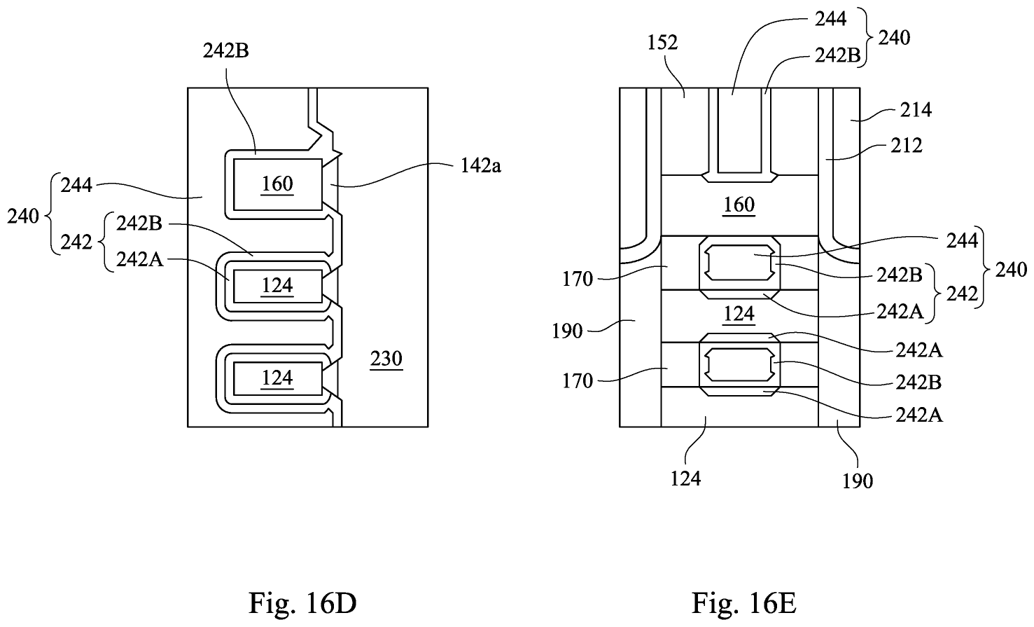

FIGS. 1-17 illustrate a method of manufacturing an integrated circuit device at various stages in accordance with some embodiments. FIGS. 1-15, 16A, and 17 are perspective views of the integrated circuit device at various manufacturing stages in accordance with some embodiments. FIG. 14B is a cross-sectional view taken along line B-B in FIG. 14A). FIGS. 16B and 16C are cross-sectional views respectively taken along line B-B and line C-C in FIG. 16A). It is understood that additional steps may be provided before, during, and after the steps shown in FIGS. 1-17, and some of the steps described below can be replaced or eliminated for additional embodiments of the method. The order of the operations/processes may be interchangeable.

As with the other method embodiments and exemplary devices discussed herein, it is understood that parts of the integrated circuit structure may be fabricated by a CMOS technology process flow, and thus some processes are only briefly described herein. Further, the exemplary integrated circuit structure may include various other devices and features, such as other types of devices such as additional transistors, bipolar junction transistors, resistors, capacitors, inductors, diodes, fuses, static random access memory (SRAM) and/or other logic circuits, etc., but is simplified for a better understanding of the concepts of the present disclosure. In some embodiments, the exemplary integrated circuit structure includes a plurality of semiconductor devices (e.g., transistors), including PFETs, NFETs, etc., which may be interconnected.

FIG. 1 illustrates a perspective view of an initial structure. The initial structure includes a substrate 110. The substrate 110 may be a bulk silicon substrate. Alternatively, the substrate 110 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible substrates 110 also include a silicon-on-insulator (SOI) substrate. SOI substrates are fabricated using separation by implantation of oxygen (SIMOX), wafer bonding, and/or other suitable methods.

An epitaxial stack 120 may be formed over the substrate 110. The epitaxial stack 120 may include epitaxial layers 122 of a first composition interposed by epitaxial layers 124 of a second composition. The first and second compositions can be different. In some embodiments, the epitaxial layers 122 are SiGe, and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below.

It is noted that four layers of the epitaxial layers 122 and three layers of the epitaxial layers 124 are alternately arranged as illustrated in FIG. 1, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of epitaxial layers 124 is between 2 and 10.

In some embodiments, each epitaxial layer 122 has a thickness ranging from about 1 nanometers (nm) to about 15 nm, but other ranges are within the scope of various embodiments of the present disclosure. The epitaxial layers 122 may be substantially uniform in thickness. In some embodiments, each epitaxial layer 124 has a thickness ranging from about 1 nm to about 15 nm, but other ranges are within the scope of various embodiments of the present disclosure. In some embodiments, the epitaxial layers 124 of the stack 120 are substantially uniform in thickness. As described in more detail below, the epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers.

In some embodiments, the stack 120 may further include an epitaxial layer 128 over the layers 122 and 124. The epitaxial layer 128 may have a composition different from that of the layers 122 and 124. For example, the epitaxial layers 122 are SiₓGe₍₁₋ₓ₎, the epitaxial layers 124 are Si_{y}Ge_{(1-y)}, and the epitaxial layers 128 is Si_{z}Ge_{(1-z)}, in which y>x>z. For example, x is in a range from about 0.05 to about 0.25, y is in a range from about 0 to about 0.01, and z is in a range from about 0.3 to about 0.5. If x is less than about 0.05, the epitaxial layers 122 and the epitaxial layers 124 may have poor etch selectivity therebetween. If x is greater than about 0.25, the epitaxial layers 122 and the epitaxial layers 128 may have poor etch selectivity therebetween. The epitaxial layers 128 in channel regions(s) may eventually be removed and serve to define a vertical distance between a portion of a metal gate surrounding the nanosheets and a portion of the metal gate receiving a gate contact. A thickness of the epitaxial layer 128 may be in a range from about 1 nanometer to about 15 nanometers. If the thickness of the epitaxial layer 128 is less than about 1 nanometer, it may be difficult to deposit dielectric material into the opening left by removing the epitaxial layer 128. If the thickness of the epitaxial layer 128 is greater than about 15 nanometers, it may be difficult to merge the dielectric material deposited in the opening left by removing the epitaxial layer 128. In some embodiments, the epitaxial layer 128 may have a thickness different from (either greater than or less than) that of the layers 122 and 124.

In some embodiments, the stack 120 may further include a thin epitaxial layer 126 spacing the epitaxial layer 128 from the topmost epitaxial layer 122. The thin epitaxial layer 126 may include a same composition as that of the epitaxial layer 124. For example, the thin epitaxial layer 126 include Si. The epitaxial stack 120 may be referred to as a super lattice in some embodiments.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 and 126 include the same material as the substrate 110. In some embodiments, the epitaxially grown layers 122-128 include a different material than the substrate 110. As stated above, in at least some examples, the epitaxial layers 122 and 128 include an epitaxially grown silicon germanium (SiGe) layer, in which a germanium concentration of the epitaxial layer 128 is greater than a germanium concentration of the epitaxial layer 122, and the epitaxial layers 124 and 126 include an epitaxially grown silicon (Si) layer. Alternatively, in some embodiments, either of the epitaxial layers 122-128 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 122-128 may be chosen based on providing differing oxidation and/or etching selectivity properties. In some embodiments, the epitaxial layers 122-128 are substantially dopant-free (i.e., having an extrinsic dopant concentration from about 0 cm⁻³ to about 1×10¹⁸ cm⁻³), where for example, no intentional doping is performed during the epitaxial growth process.

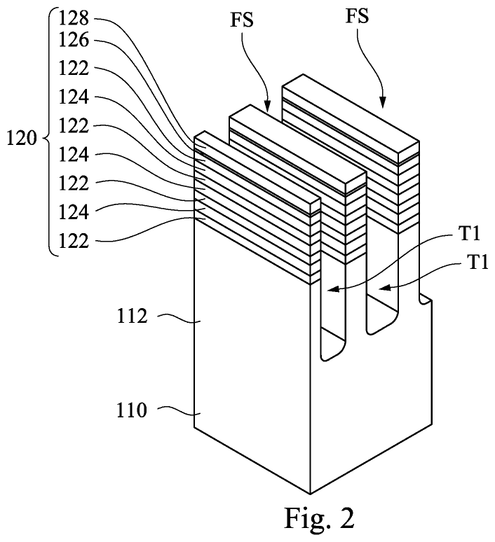

FIG. 2 illustrates formation of semiconductor fins FS extending from the substrate 110. In various embodiments, each of the fins FS includes a portion 112 of the substrate 110 and portions of each of the epitaxial layers of the epitaxial stack including epitaxial layers 122, 124, 126, and 128. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120 (illustrated in FIG. 1). The etching process can include dry etching, wet etching, reactive ion etching (RIE), and/or other suitable processes.

The fins FS may subsequently be fabricated using suitable processes including photolithography and etch processes. The photolithography process may include forming a photoresist layer (not shown) over the substrate 110 and layers formed thereupon, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region. The patterned mask may then be used to protect regions of the substrate 110, and layers formed thereupon, while an etch process forms trenches T1 in unprotected regions through the patterned mask, through the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

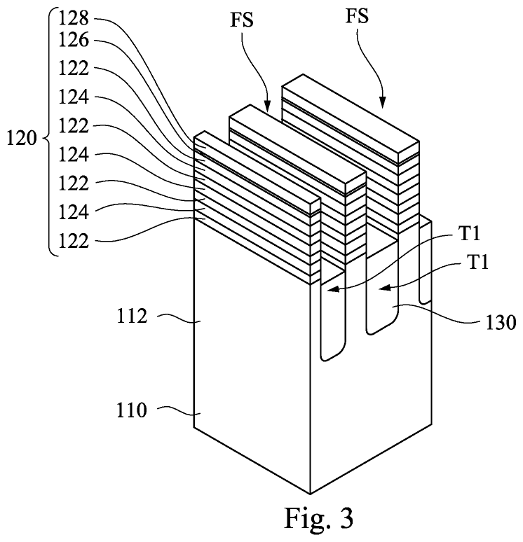

FIG. 3 illustrates formation of isolation structures 130 in the trenches T1 between the fins FS. By way of example and not limitation, a dielectric layer is first deposited over the substrate 110, filling the trenches T1 with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an ALD process, a physical vapor deposition (PVD) process, and/or other suitable processes. In some embodiments, after deposition of the dielectric layer, the integrated circuit structure may be annealed, for example, to improve the quality of the dielectric layer. A chemical mechanical polishing (CMP) process may be performed to thin and planarize the deposited dielectric layer, remaining portions of the dielectric layer form the isolation structures 130 between the fins FS. The isolation structures 130 are recessed by an etch back process, thereby providing the fins FS having exposed sidewalls extending above the etched back isolation structure 130. The etched back isolation structures 130 may be referred to as shallow trench isolation (STI) structures. As shown in the figures, a top surface of the fins FS may be higher than a top surface of the isolation structures 130. In some embodiments, the recessing process may include a dry etching process, a wet etching process, and/or a combination thereof. A recessing depth may be controlled (e.g., by controlling an etching time) so as to result in a target height of the exposed upper portion of the fins FS. In the illustrated embodiments, the target height exposes each of the epitaxial layers 122 and 124 of the epitaxial stack 120 in the fins FS. In some embodiments, the isolation structures 130 may include a multi-layer structure, for example, having one or more liner layers. In the context, the isolation structure 130 may define oxide defined (OD) regions (e.g., fins FS).

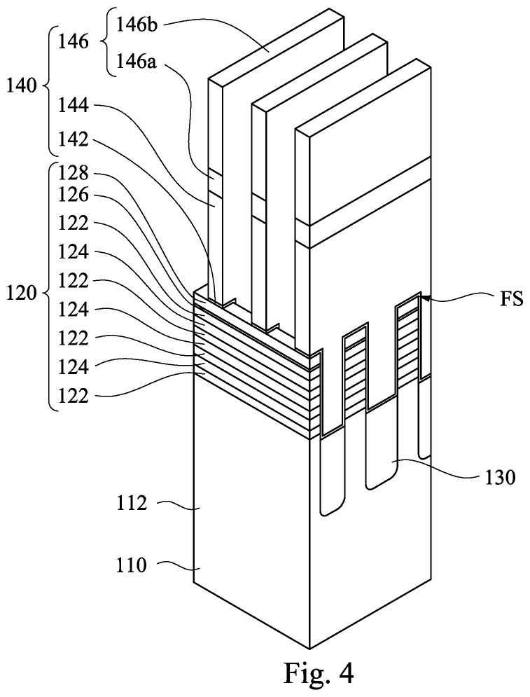

FIG. 4 illustrates formation of gate structures 140. In some embodiments, the gate structures 140 are dummy (sacrificial) gate structures that are subsequently removed. Thus, in some embodiments using a gate-last process, the gate structures 140 are dummy gate structures and will be replaced by the final gate structures at a subsequent processing stage of the integrated circuit device. In particular, the dummy gate structures 140 may be replaced at a later processing stage by a high-k dielectric layer (HK) and metal gate electrode (MG) as discussed below. In some embodiments, the dummy gate structures 140 are formed over the substrate 110 and are at least partially disposed over the fins FS. The portion of the fins FS underlying the dummy gate structures 140 may be referred to as the channel region. The dummy gate structures 140 may also define a source/drain (S/D) region of the fins FS, for example, the regions of the fin FS adjacent and on opposing sides of the channel region.

In the illustrated embodiments, the formation of the gate structures 140 first forms a dummy gate dielectric layer 142 over the fins FS. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structure). Subsequently, the formation of the gate structures 140 forms a dummy gate electrode layer 144 and a hard mask 146 which may include multiple layers (e.g., a nitride layer 146a and an oxide layer 146b).

In some embodiments, the dummy gate structure 140 is formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structure for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the dummy gate electrode layer 144 may include polycrystalline silicon (polysilicon). In some embodiments, the hard mask 146 includes a nitride layer 146a such as Si₃N₄ and/or silicon oxynitride and an oxide layer 146b such as SiO₂. In some embodiments, after patterning the dummy gate electrode layer 144, the dummy gate dielectric layer 142 is removed from the S/D regions of the fins FS. The etch process may include a wet etch, a dry etch, and/or a combination thereof. The etch process is chosen to selectively etch the dummy gate dielectric layer 142 without substantially etching the fins FS and the dummy gate electrode layer 144. Through the steps, the dummy gate structure 140 are formed across the semiconductor fins FS.

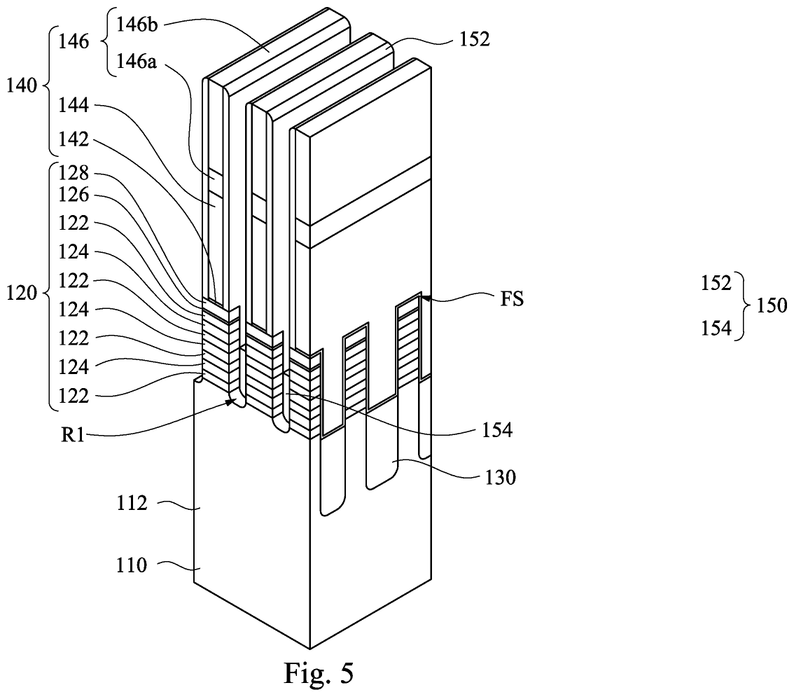

Reference is made to FIG. 5. After the formation of the dummy gate structures 140, gate spacers 152 are formed on sidewalls of the dummy gate structures 140. For example, a spacer material layer is conformally deposited on the substrate using processes such as, CVD process, a subatmospheric CVD (SACVD) process, a flowable CVD process, an ALD process, a PVD process, or other suitable process. The spacer material layer may include a dielectric material such as silicon oxide, silicon nitride, silicon carbide, silicon oxynitride, SiCN films, silicon oxycarbide, SiOCN films, and/or combinations thereof. The spacer material layer is subsequently etched back to form the gate spacers 152. For example, an anisotropic etching process is performed on the deposited spacer material layer to expose portions of the fins FS not covered by the dummy gate structures 140 (e.g., in source/drain regions of the fins FS). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 152, for the sake of simplicity. In some embodiments, portions of the spacer material layer on sidewalls of the fins FS may remain, forming fin sidewall spacers, which are denoted as fin sidewall spacers 154, for sake of simplicity. In some embodiments, the spacer material layer includes multiple layers, and therefore the gate spacers 152 and the fin sidewall spacers 154 may be multi-layer structures.

Portions of the semiconductor fins FS that extend laterally beyond the gate spacers 152 (e.g., in source/drain regions of the fins FS) are etched by using, for example, an anisotropic etching process that uses the dummy gate structures 140, the gate spacers 152 as an etch mask, resulting in recesses R1 into the fins FS and between corresponding dummy gate structures 140. The recesses R1 may expose end surfaces (or sidewalls) of the layers 122-128. After the anisotropic etching, end surfaces of the sacrificial layers 122 and channel layers 124 are substantially aligned with respective outermost sidewalls of the gate spacers 152, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof. In some embodiments, the isolation structure 130 may have a higher etch resistance to the anisotropic etching process than that of the semiconductor fins FS, and thus not substantially etched.

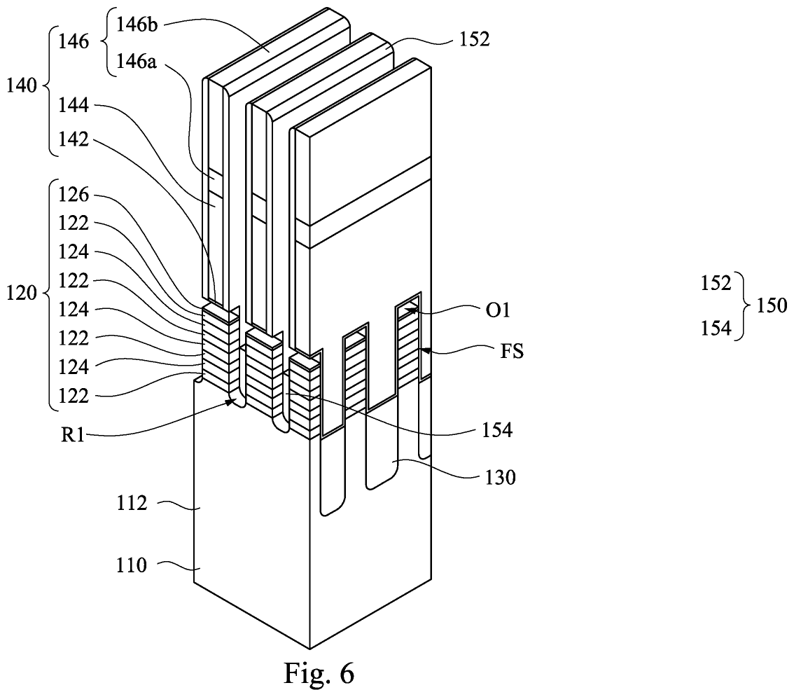

Reference is made to FIG. 6. The epitaxial layer 128 is etched by using a selective etching process that etches the sacrificial layers 128 at a faster etch rate than it etches the epitaxial layers 122, 124, and 126 and the gate spacer 152, thus forming openings O1 between the gate dielectric layer 142 and the epitaxial layer 126. At this interim processing step, the openings O1 between the gate dielectric layer 142 and the epitaxial layer 126 may be filled with ambient environment conditions (e.g., air, nitrogen, etc).

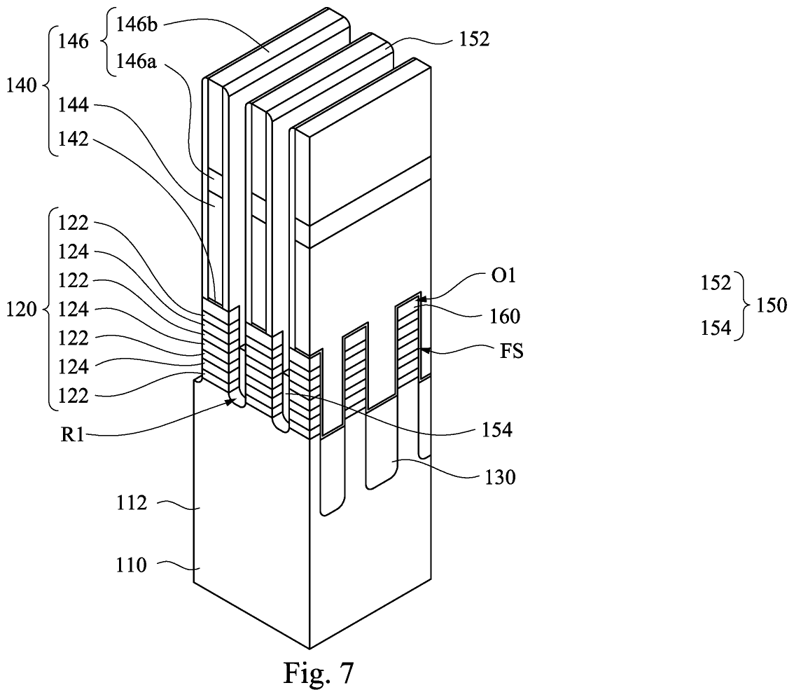

Reference is made to FIG. 7. A dielectric layer 160 is formed to fill the openings O1 left by the etching of the epitaxial layer 128. Formation of the dielectric layer 160 may include depositing a dielectric material into the recess R1 and the openings O1 and removing a portion of the dielectric material in the recess R1 and outside the openings O1. The dielectric material may be a low-k dielectric material (with dielectric constant lower than about 7), such as SiO₂, SiN, SiCN, or SiOCN, the like, or the combination thereof. The dielectric material may be formed by a suitable deposition method, such as ALD. After the deposition of the dielectric material, an anisotropic etching process may be performed to trim the deposited dielectric material, thereby removing the portion of the dielectric material in the recess R1 and outside the openings O1. After the anisotropic etching process, only portions of the deposited dielectric material that fill the openings O1 remains, and the remaining portions of the deposited dielectric material are denoted as a dielectric layer 160. Formation of the dielectric layer 160 is performed such that the end surfaces (or sidewalls) of the epitaxial layers 122 and 124 remain exposed in the recess R1. The dielectric layer 160 may include Si, O, C, or N, and may optionally have an air gap therein. In the example of FIG. 7, sidewalls of the dielectric layer 160 may be vertically aligned with sidewalls of the layers 122 and 124. In some other embodiments, sidewalls of the dielectric layer 160 are laterally set back from sidewalls of the layers 122 and 124. A thickness of the dielectric layer 160 may be in a range from about 1 nanometer to about 15 nanometers, depending on the thickness of the epitaxial layer 128.

In some embodiments, prior to the deposition of the dielectric material of the dielectric layer 160, a cleaning process may be optionally performed, and the epitaxial layer 126 (referring to FIG. 6) is removed by the cleaning process, leaving the epitaxial layer 122 exposed. Thus, the formed dielectric layer 160 may be in contact with the epitaxial layer 122. In some alternative embodiments, the epitaxial layer 126 (referring to FIG. 6) may remain, and the formed dielectric layer 160 may be in contact with the epitaxial layer 126 (referring to FIG. 6).

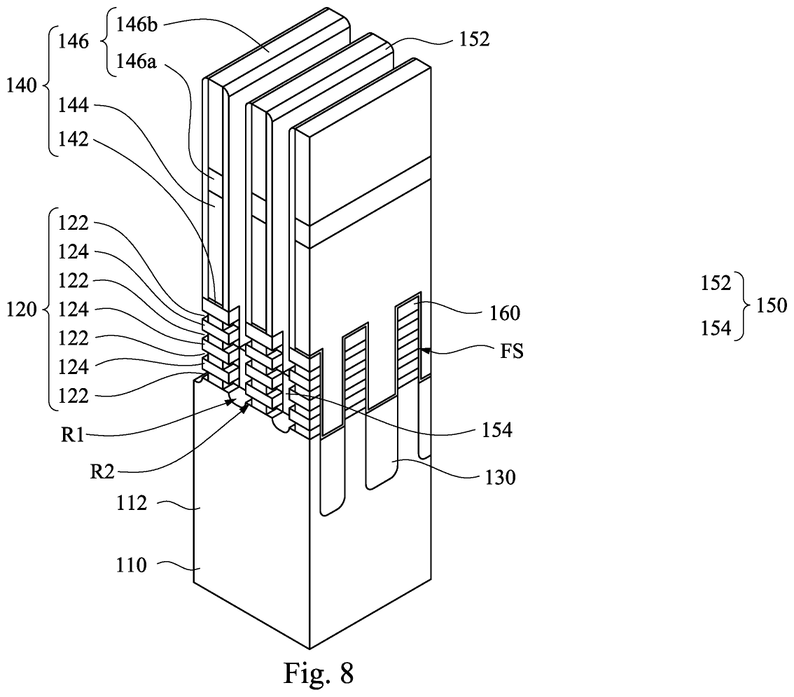

Reference is made to FIG. 8. The sacrificial layers 122 are laterally or horizontally recessed by using suitable etch techniques, resulting in lateral recesses R2 each vertically between corresponding channel layers 124. This step may be performed by using a selective etching process. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 remain substantially intact during laterally recessing the sacrificial layers 122. As a result, the channel layers 124 laterally extend past opposite end surfaces of the sacrificial layers 122.

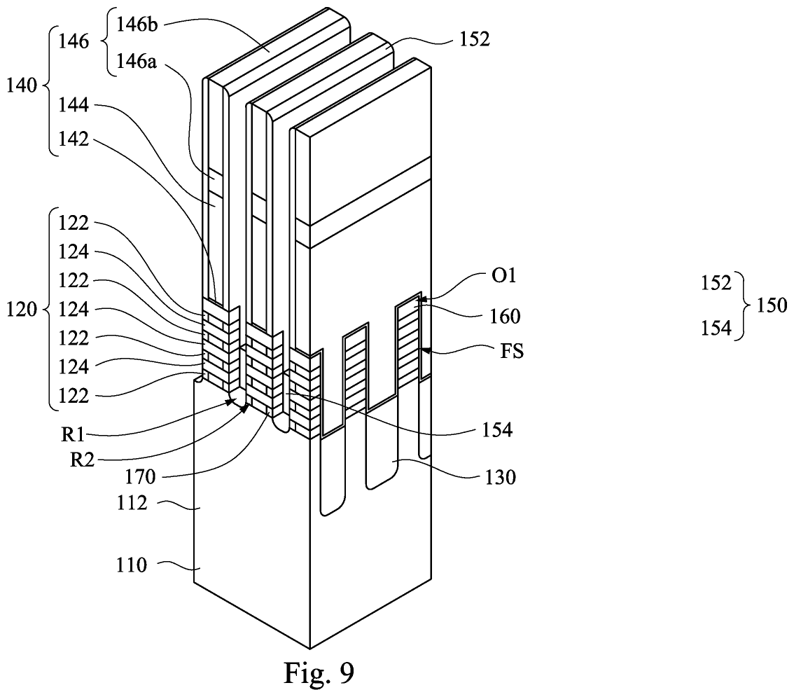

Reference is made to FIG. 9. After the sacrificial layers 122 have been laterally recessed, an inner spacer material is formed to fill the recesses R2 left by the lateral etching of the sacrificial layers 122. The inner spacer material may be a low-k dielectric material (with dielectric constant lower than about 7), such as SiO₂, SiN, SiCN, or SiOCN, the like, or the combination thereof. The inner spacer material may be formed by a suitable deposition method, such as ALD. After the deposition of the inner spacer material, an anisotropic etching process may be performed to trim the deposited inner spacer material, such that only portions of the deposited inner spacer material that fill the recesses R2 left by the lateral etching of the sacrificial layers 122 are left. After the trimming process, the remaining portions of the deposited inner spacer material are denoted as inner spacers 170, for the sake of simplicity. The inner spacers 170 serve to isolate metal gates from source/drain epitaxial structures formed in subsequent processing. In the example of FIG. 9, sidewalls of the inner spacers 170 may be vertically aligned with sidewalls of the channel layers 124. In some other embodiments, sidewalls of the inner spacers 170 are laterally set back from sidewalls of the channel layers 124.

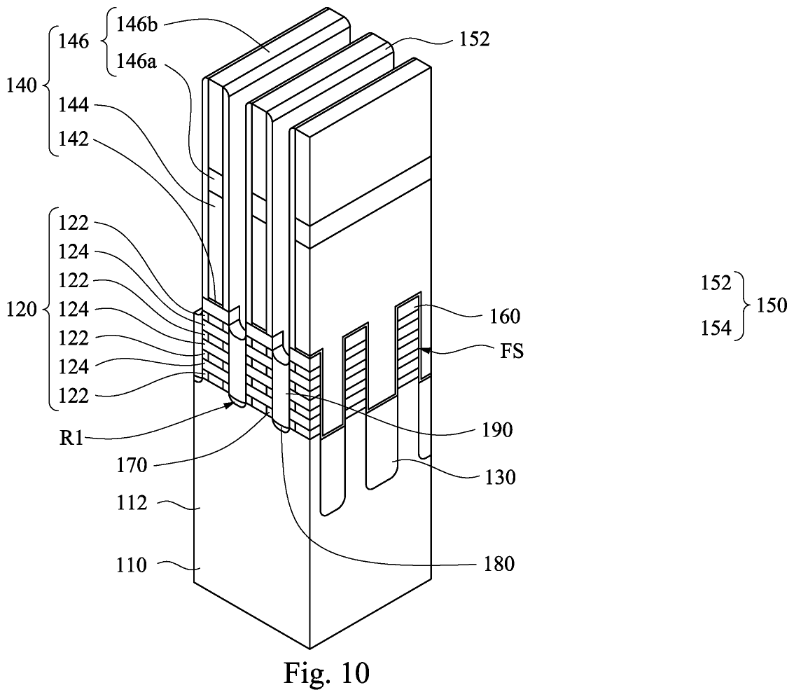

Reference is made to FIG. 10. After the formation of the inner spacers 170, source/drain epitaxial structures 190 are formed in the recesses R1 in the fins FS. The source/drain epitaxial structures 190 may be formed by performing an epitaxial growth process that provides an epitaxial material on the fins FS. During the epitaxial growth process, the dummy gate structures 140, the gate spacers 152, and the fin sidewall spacers 154 limit the source/drain epitaxial structures 190 to the source/drain regions in the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the substrate 110 and the channel layers 124. In some embodiments, after the epitaxial growth process, a top surface of the source/drain epitaxial structures 190 may be lower than a top surface of the dielectric layer 160 and above a top surface of a topmost one of the channel layers 124. In some further embodiments, the top surface of the source/drain epitaxial structures 190 may be lower than a bottom surface of the dielectric layer 160 and above the top surface of the topmost one of the channel layers 124.

In some embodiments, the source/drain epitaxial structures 190 may include Ge, Si, GaAs, AlGaAs, SiGe, GaAsP, SiP, or other suitable material. The source/drain epitaxial structures 190 may be in-situ doped during the epitaxial process by introducing doping species including: p-type dopants, such as boron; n-type dopants, such as phosphorus or arsenic; and/or other suitable dopants including combinations thereof. If the source/drain epitaxial structures 190 are not in-situ doped, an implantation process (i.e., a junction implant process) is performed to dope the source/drain epitaxial structures 190. In some exemplary embodiments, the source/drain epitaxial structures 190 in an NFET device include SiP, while those in a PFET device include GeSnB and/or SiGeSnB.

In some embodiments, prior to the formation of the source/drain epitaxial structures 190, an isolation layer 180 may be optionally formed in the recess R1. The isolation layer 180 may include SiO₂, SIN, SiCN, SiOC, SiOCN, other low-k dielectric materials (with dielectric constant lower than about 7), the like, or the combination thereof. In some embodiments, the isolation layer 180 is deposited by deposition and etch processes, and thus the isolation layer 180 may be located at the bottom of the recess R1, leaving the channel layers 124 exposed. The configuration of the isolation layer 180 can reduce the capacitances between gate and source/drain regions, leakage from source/drain regions to the well region (both source cutoff current (ISoff), and junction capacitance between the source/drain regions and the well region. The dielectric material may include silicon oxide, silicon nitride, silicon oxynitride, the like, or the combination thereof. The isolation layer 180 can be a single dielectric layer, or multiple dielectric layers. In some embodiments, for allowing growth of the source/drain epitaxial structures 190 from the bottommost channel layer 124, a top surface of the isolation layer 180 is lower than a bottom surface of the bottommost channel layer 124. In some alternative embodiments, the isolation layer 180 may be omitted.

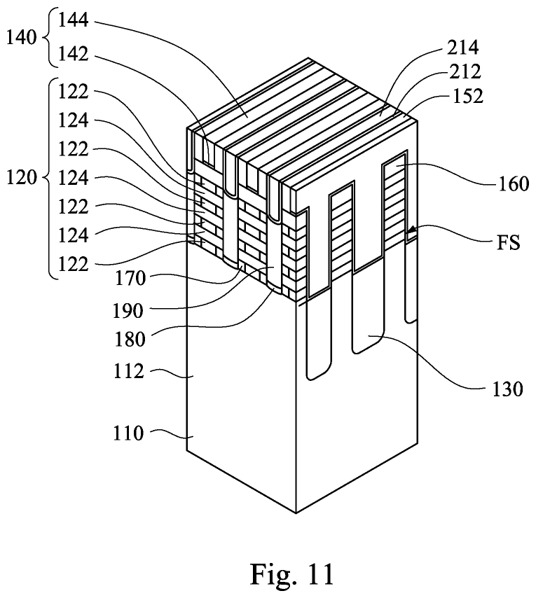

Reference is made to FIG. 11. After the formation of the source/drain epitaxial structures 190, a CESL 212 may be deposited. In some examples, the CESL 212 includes a silicon nitride layer, silicon oxide layer, a silicon oxynitride layer, and/or other suitable materials. The CESL 212 may be formed by plasma-enhanced chemical vapor deposition (PECVD) process and/or other suitable deposition or oxidation processes. An interlayer dielectric (ILD) layer 214 is then deposited over the CESL 212. In some embodiments, the ILD layer 214 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 212. The ILD layer 214 may be deposited by a PECVD process or other suitable deposition technique. In some embodiments, after formation of the ILD layer 214, the integrated circuit device may be subject to a high thermal budget process to anneal the ILD layer 214.

After depositing the ILD layer 214, a planarization process may be performed to remove excessive materials of the CESL 212 and the ILD layer 214. For example, a planarization process includes a chemical mechanical planarization (CMP) process which removes portions of the ILD layer 214 and the CESL 212 overlying the dummy gate structures 140 and planarizes a top surface of the integrated circuit device. In some embodiments, the CMP process also removes the hard mask 146 in the dummy gate structures 140 (as shown in FIG. 10) and exposes the dummy gate electrode layer 144.

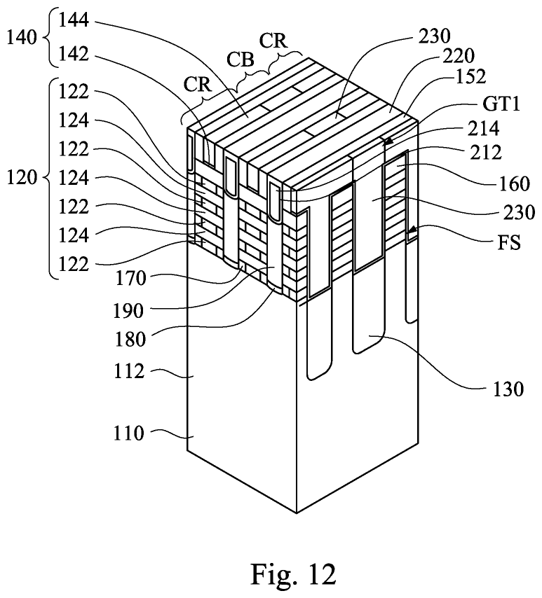

Reference is made to FIG. 12. Gate isolation structures 230 are formed in the dummy gate electrode layer 144. For example, at least one first portion of the dummy gate electrode layer 144 is replaced with a gate isolation structure 230. Referring to FIG. 12, the first portions of the dummy gate electrode 144 over the isolation structure 130 at a boundary region CB between cell regions CR are removed, and second portions of the dummy gate electrode 144 in the cell regions CR remain unremoved. The removal of the first portions of the dummy gate electrode 144 may be performed by using suitable photolithography and etching techniques. For example, a patterned mask is formed over the cell regions CR and exposing the boundary region CB, and materials in the boundary region can be removed by suitable etching techniques. In the illustrated embodiments, the first portions of the dummy gate electrode 144 are removed by using a selective etching process (e.g., selective dry etching, selective wet etching, or a combination thereof) that etches the materials in dummy gate electrode 144 at a faster etch rate than it etches other materials (e.g., the dummy gate dielectric layer 142, the gate spacers 152, the CESL 212 and/or dielectric cap), thus resulting in gate trenches GT1 between corresponding gate spacers 152 in the boundary region CB.

Subsequently, the gate isolation structures 230 are formed in the gate trenches GT1. Formation of the gate isolation structures 230 includes depositing a dielectric material into the gate trench GT1, followed by a planarization process. The deposited dielectric material may be SiO₂, SIN, SiCN, SiOC, SiOCN, other low-k dielectric materials (with dielectric constant lower than about 7), the like, or the combination thereof. The dielectric material may be formed by a suitable deposition method, such as CVD, ALD, the like, or the combination thereof. The planarization process (e.g., CMP process) may remove a portion of the dielectric material external to the gate trench GT1 (e.g., higher than a top surface of the dielectric cap and top surfaces of the second portions of the dummy gate electrode 144), such that remaining portions of the dielectric material form the gate isolation structures 230. Each of the gate isolation structures 230 adjoining sides of two fins FS. In FIG. 12, two fins FS adjoining the gate isolation structures 230 may correspond to a transistor having a conductive type different to a conductive type of a transistor that a fin FS away from the gate isolation structures 230 corresponds to. For example, the two fins FS adjoining the gate isolation structures 230 may correspond to n-type transistors, and the fin FS away from the gate isolation structures 230 may correspond to a p-type transistor. Alternatively, the two fins FS adjoining the gate isolation structures 230 may correspond to p-type transistors, and the fin FS away from the gate isolation structures 230 may correspond to a n-type transistor. In context, the gate isolation structure 230 may also be referred to as a dielectric wall.

In some embodiments, prior to forming the gate isolation structures 230, top surfaces of the ILD layer 214 are recessed, and dielectric hard masks 220 are formed over the recessed top surfaces of the ILD layer 214. The dielectric hard masks 220 may protect the ILD layer 214 from being etched during one or more subsequent etching processes.

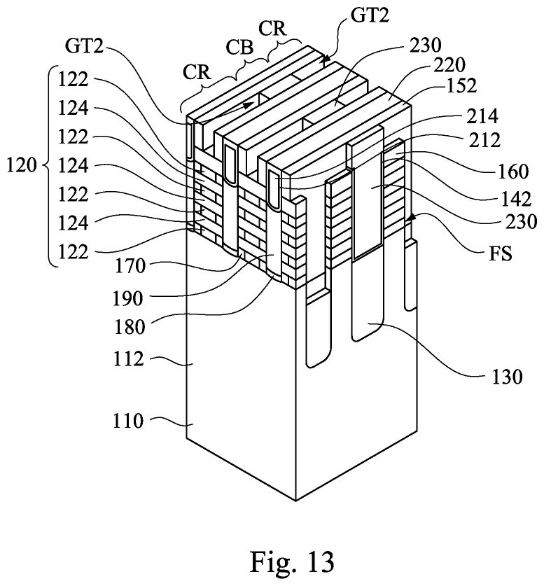

FIGS. 13-15 illustrates replacing second portions of the dummy gate electrode layer 144 and the sacrificial layers 122 with high-k/metal gate structures 200. Referring to FIG. 13, the second portions of the dummy gate electrode 144 in the cell regions CR are removed. The removal of the second portions of the dummy gate electrode 144 may be performed by an etch back process. In the illustrated embodiments, the second portions of the dummy gate electrode 144 are removed by using a selective etching process (e.g., selective dry etching, selective wet etching, or a combination thereof) that etches the materials in dummy gate electrode 144 at a faster etch rate than it etches other materials (e.g., the dummy gate dielectric layer 142, the gate spacers 152, the gate isolation structures 230, the CESL 182 and/or dielectric caps), thus resulting in gate trenches GT2 between corresponding gate spacers 152 and between the gate isolation structures 230 in the cell region CR.

In the illustrated embodiments, portions of the dummy gate dielectric layer 142 exposed by the gate trenches GT2 are removed by an oxide removal process, such that a first side of the fins FS including the sacrificial layers 122 and the channel layers 124 are exposed in the gate trenches GT2, while a second side of the fins FS including the sacrificial layers 122 and the channel layers 124 remain covered by remaining portions of the dummy gate dielectric layer 142 below the gate isolation structures 230. The oxide removal process may include a dry etch, a wet etch, or the combination thereof. The oxide removal process may use an isotropic etching process. The oxide removal process etches the dummy gate dielectric layer 142 at a faster etch rate than it etches other materials (e.g., the gate spacers 152 and the gate isolation structures 230). Due to the presence of the gate isolation structures 230, the portion of the dummy gate dielectric layer 142 below the gate isolation structures 230 may not be etched.

Referring to FIGS. 14A and 14B, the sacrificial layers 122 in the gate trenches GT2 are etched by using a selective etching process that etches the sacrificial layers 122 at a faster etch rate than it etches the channel layers 124, thus forming openings O2 between neighboring channel layers 124 and between the bottommost channel layer 124 and the substrate portion 112. In this way, the channel layers 124 become nanosheets suspended over the substrate 110 and between the source/drain epitaxial structures 190. This step is also called a channel release process or “sheet formation” (SHF) process. At this interim processing step, the openings O2 between nanosheets 124 and between the bottommost channel layer 124 and the substrate portion 112 may be filled with ambient environment conditions (e.g., air, nitrogen, etc). In some embodiments, the nanosheets 124 can be interchangeably referred to as nanowires, nanoslabs and nanorings, depending on their geometry. For example, in some other embodiments, the channel layers 124 may be trimmed to have a substantial rounded shape (i.e., cylindrical) due to the selective etching process for completely removing the sacrificial layers 122 (referring to FIG. 13). In that case, the resultant channel layers 124 can be called nanowires.

In some embodiments, the sacrificial layers 122 (referring to FIG. 13) are removed by using a selective wet etching process. In some embodiments, the sacrificial layers 122 are SiGe and the channel layers 124 are silicon allowing for the selective removal of the sacrificial layers 122 (referring to FIG. 13). In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

In FIG. 14B, a portion of the dummy gate dielectric layer 142 between the gate isolation structures 230 and a side of the fin FS (referring to FIG. 13) are trimmed, thereby creating spaces for pi-gate subsequently formed. Through the trimming process, the portion of the dummy gate dielectric layer 142 between the gate isolation structures 230 and a side of the fin FS (referring to FIG. 13) is cut into a dielectric element 142a, dielectric elements 142b and a dielectric layer 142c below the gate isolation structure 230. The trimming process may include a dry etch, a wet etch, or the combination thereof. The trimming process may use an isotropic etching process. The isotropic etching process etches the portion of the dummy gate dielectric layer 142 (referring to FIG. 13) at a faster etch rate than it etches other materials (e.g., the gate spacers 152 and the gate isolation structures 230). After the trimming process, recesses R3a are formed among the dielectric layer 160, the gate isolation structure 230, and the dielectric elements 142a, and recesses R3b are formed among the channel layer 124, the gate isolation structure 230, and the dielectric elements 142b.

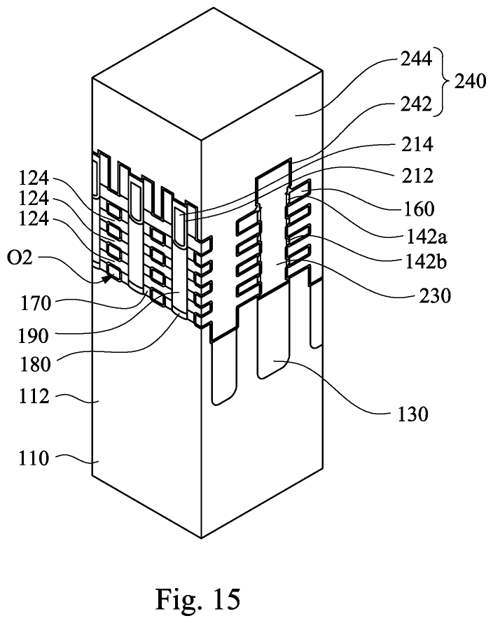

Referring to FIG. 15, the high-k/metal gate structures 240 are respectively formed in the gate trenches GT2 to surround each of the nanosheets 124 suspended in the gate trenches GT2. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 124. For example, high-k/metal gate structures 240 are formed within the openings O2 provided by the release of nanosheets 124. In various embodiments, the high-k/metal gate structure 240 includes a gate dielectric layer 242 formed around the nanosheets 124 and a gate metal layer 244 formed around the gate dielectric layer 242 and filling a remainder of gate trenches GT2. Formation of the high-k/metal gate structures 240 may include one or more deposition processes to form various gate materials.

The gate dielectric layer 242 may include an interfacial layer 242A (referring to FIGS. 16D and 16E later) formed around the nanosheets 124 and a high-k dielectric layer 242B (referring to FIGS. 16D and 16E later) formed around the interfacial layer 242A. In some embodiments, the interfacial layer 242A (referring to FIGS. 16D and 16E later) is silicon oxide formed on exposed surfaces of semiconductor materials in the gate trenches GT2 by using, for example, thermal oxidation, chemical oxidation, wet oxidation or the like. In some embodiments, the high-k dielectric layer 242B (referring to FIGS. 16D and 16E later) includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. The high-k dielectric layer 242B (referring to FIGS. 16D and 16E later) may be deposited by suitable ALD, CVD, the like, or the combination thereof.

In some embodiments, the gate metal layer 244 includes one or more metal layers. For example, the gate metal layer 244 may include one or more work function metal layers stacked one over another and a fill metal filling up a remainder of gate trenches GT2. The one or more work function metal layers in the gate metal layer 244 provide a suitable work function for the high-k/metal gate structures 240. For an n-type GAA FET, the gate metal layer 244 may include one or more n-type work function metal (N-metal) layers. The n-type work function metal may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type GAA FET, the gate metal layer 244 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 244 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

After the deposition processes to form various gate materials, a CMP process is performed to remove excessive gate materials, resulting in the high-k/metal gate structures 240 having top surfaces level with a top surface of the ILD layer 214. The resulted structure is shown in FIGS. 16A-16C. The CMP process may also remove the dielectric hard masks 220 (referring to FIG. 15) over the ILD layers 214. As illustrated in of FIGS. 16A-16C, the high-k/metal gate structure 240 surrounds/wraps the dielectric layer 160 and each of the nanosheets 124, and thus is referred to as a gate of a GAA FET.

In FIG. 16B, the high-k/metal gate structure 240 may extend into the recesses R3b, and thus have a pi-gate shape, which is beneficial for short channel control. For example, in the present embodiments, the gate dielectric layer 242 may extend into the recess R3b, and little or no gate metal layer 244 may extend into the recess R3b. In some alternative embodiments, both the gate dielectric layer 242 and the gate metal layer 244 may extend into the recess R3b and fill a remainder of the recess R3b.

In some embodiments of the present disclosure, with the dielectric layer 160, the nanosheets 124 are well and uniformly protected during the fabrication process. As a result, the nanosheets 124 may have substantially a same and uniform thickness. Also, with the presence of the dielectric layer 160, plural portions of the high-k/metal gate structures 240 adjacent the nanosheets 124 may have a uniform height 240Ha. For example, a portion of the high-k/metal gate structures 240 vertically between the nanosheets 124 have a height substantially equal to a height of a portion of the high-k/metal gate structures 240 vertically between the dielectric layer 160 and a topmost one of the nanosheets 124. With the uniform nanosheet thickness and the uniform gate height, characteristics of the plural transistors are uniform, and the cell capacitance to the environment is reduced, thereby improving the logic cell speed. For example, the height 240Ha of the portions of the high-k/metal gate structures 240 may be in a range from about 3 nanometers to about 15 nanometers, with a variation of plus or minus 3 nanometers. If the height 240Ha is less than about 3 nanometers, it may be hard to deposit materials of the high-k/metal gate structures 240 into opening between nanosheets 124. If the height 240Ha is greater than about 15 nanometers, the device size may be enlarged unnecessarily.

In FIG. 16B, a height 240Hb of a portion of the high-k/metal gate structure 240 above the dielectric layer 160 may be in a range from about 5 nanometers to about 25 nanometers. If the height 240Hb is greater than about 25 nanometers, the device size may be too large, and the effective cell capacitance of the gate to other elements may increase. If the height 240Hb is less than about 5 nanometers, it is difficult to flow current to the entire gate metal layer 244, for example, from a gate contact via landed on the gate metal layer 244 over the nanosheets 124.

In FIG. 16C, a width 240Wa of the portions of the high-k/metal gate structures 240 adjacent the nanosheets 124 may be in a range from about 8 nanometers to about 20 nanometers, depending on technology nodes. In some embodiments, a width 240Wb of the portions of the high-k/metal gate structures 240 above the dielectric layer 160 may be less than the width 240Wa of the portions of the high-k/metal gate structures 240 adjacent the nanosheets 124. This configuration may reduce a capacitance between source/drain contact and gate, and the cell capacitance to the environment is reduced, thereby improving the logic cell speed. The widths 240Wa and 240Wb of the portions of the high-k/metal gate structures 240 may be adjusted by tuning the thickness of the gate spacers 152 and the inner spacers 170. In some other embodiments, a width 240Wb of the portions of the high-k/metal gate structures 240 above the dielectric layer 160 may be equal to the width 240Wa of the portions of the high-k/metal gate structures 240 adjacent the nanosheets 124.

FIGS. 16D and 16E are enlarged views of portions of FIGS. 16B and 16C, respectively. The high-k/metal gate structures 240 may have the high-k dielectric layer 242B in contact with the dielectric layer 160 and the interfacial layer 242A in contact with the nanosheets 124. As shown in the cross-sectional view of FIG. 16E, the portion of the high-k/metal gate structures 240 above the dielectric layer 160 may include the high-k dielectric layer 242B in direct contact with the dielectric layer 160 and be free of the interfacial layer 242A. The portion of the high-k/metal gate structures 240 between the topmost nanosheet 124 and the dielectric layer 160 may include the high-k dielectric layer 242B in direct contact with the dielectric layer 160 and the interfacial layer 242A spacing the high-k dielectric layer 242B from the nanosheets 124. The portion of the high-k/metal gate structures 240 between the two nanosheets may include the high-k dielectric layer 242B and the interfacial layer 242A spacing the high-k dielectric layer 242B from the nanosheets 124.

In the context, the high-k/metal gate structures 240 may have a metal-gate height GH above the topmost nanosheet 124. For example, the metal-gate height GH is defined as a sum of a height of a first portion of the high-k/metal gate structures 240 over the dielectric layer (e.g., the height 240Hb), a thickness of the dielectric layer 160, and a height of a second portion between the dielectric layer 160 and the topmost nanosheet 124 (e.g., the height 240Ha). For device performance, the metal-gate height GH may be in a range from about 19 nanometers to about 40 nanometers. If the metal-gate height GH is greater than about 40 nanometers, the effective cell capacitance of the gate to other elements may increase. If the metal-gate height GH is less than about 19 nanometers, it may be difficult to flow current to the entire gate metal layer 244, for example, from a gate contact via landed on the gate metal layer 244 over the nanosheets 124.

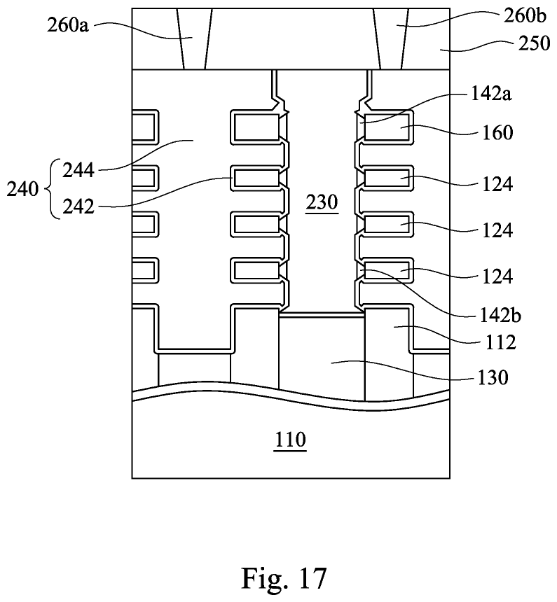

Reference is made to FIG. 17. An ILD layer 250 is deposited over the structure of FIGS. 16A-16C, and then gate contact vias 260a and 260b are formed in the ILD layer 250 and over the gate metal layer 244 of the high-k/metal gate structures 240. In some embodiments, the gate contact via 260a is landing on a portion of the gate metal layer 244 over the isolation structures 130, and the gate contact via 260b is landing on a portion of the gate metal layer 244 over the nanosheets 124. For example, the gate contact via 260a is vertically aligned with the isolation structures 130, and the gate contact via 260b is vertically aligned with the nanosheets. The gate contact vias 260a and 260b are designed/chosen according to routing requirements. The gate contact vias 260a and 260b may have substantially the same height with a variation of plus or minus 3 nanometers.

In some embodiments, the ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be deposited by a PECVD process or other suitable deposition technique. In some embodiments, after formation of the ILD layer 250, the integrated circuit device may be subject to a high thermal budget process to anneal the ILD layer 214. Formation of the gate contact vias 260a and 260b may include etching gate contact openings in the ILD layer 250 to expose the gate metal layer 244, depositing one or more metal materials (e.g., tungsten, cobalt, copper, the like or combinations thereof) to fill the gate contact openings by using suitable deposition techniques (e.g., CVD, PVD, ALD, the like or combinations thereof), followed by a CMP process to remove excess metal materials outside the gate contact openings. Remaining portions of the deposited metal materials form the gate contact vias 260a and 260b.

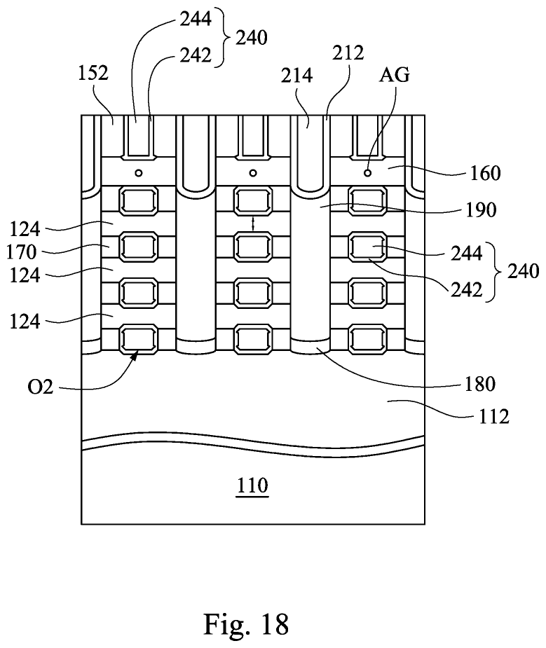

FIG. 18 is a cross-sectional view of an integrated circuit device at various stages in accordance with some embodiments. Details of the present embodiments are similar to those illustrated in FIGS. 1-17, except that the dielectric layer 160 is formed (as the step illustrated in FIG. 7) with an air gap AG therein. A dielectric material is deposited to fill the openings O1 (referring to FIG. 6) left by the etching of the epitaxial layer 128. The deposition process may be controlled such that the dielectric materials in the openings O1 are merged with an air gap AG therein. The air gap AG may be encircled by the dielectric layer 160. After the deposition of the dielectric material, an anisotropic etching process may be performed to trim the deposited dielectric material, such that only portions of the deposited dielectric material that fill the openings O1 left. After the trimming process, the remaining portions of the deposited dielectric material are denoted as a dielectric layer 160, for the sake of simplicity. Other details of the present embodiments are similar to those described above, and therefore not repeated herein.

Based on the above discussions, it can be seen that the present disclosure offers advantages over GAA devices. It is understood, however, that other embodiments may offer additional advantages, and not all advantages are necessarily disclosed herein, and that no particular advantage is required for all embodiments. One advantage is that by replacing a semiconductor layer over nanosheets with a dielectric layer, the nanosheets can be formed with a uniform height, thereby improving logic cell speed. Another advantage is that the metal gate around the nanosheet can also be formed with a uniform height.

According to some embodiments of the present disclosure, a method for manufacturing an integrated circuit device is provided. The method includes depositing an epitaxial stack over a semiconductor substrate, wherein the epitaxial stack comprises a plurality of first and second semiconductor layers alternatively arranged over the semiconductor substrate and a third semiconductor layer over the first and second semiconductor layers; patterning the epitaxial stack to form a semiconductor fin; forming a dummy gate structure over the semiconductor fin; replacing the third semiconductor layer in the semiconductor fin with a dielectric layer; and replacing the dummy gate structure and first semiconductor layers in the semiconductor fin with a metal gate structure.

According to some embodiments of the present disclosure, a method for manufacturing an integrated circuit device is provided. The method includes depositing an epitaxial stack over a semiconductor substrate, wherein the epitaxial stack comprises a first semiconductor layer, a second semiconductor layer over the first semiconductor layer, a third semiconductor layer over the second semiconductor layer, and a fourth semiconductor layer over the third semiconductor layer; patterning the epitaxial stack to form a semiconductor fin; forming a dummy gate structure over the semiconductor fin; etching a source/drain recess in the semiconductor fin to expose sidewalls of the first to fourth semiconductor layers in the semiconductor fin; etching away the fourth semiconductor layer to leave an opening between the dummy gate structure and the third semiconductor layer; forming a dielectric layer in the opening between the dummy gate structure and the third semiconductor layer; and forming a source/drain epitaxial structure in the source/drain recess after forming the dielectric layer.

According to some embodiments of the present disclosure, the integrated circuit device includes a plurality of channel layers vertically spaced apart from each other; a dielectric layer above and spaced apart from the channel layers; a metal gate structure surrounding the channel layers and the dielectric layer, wherein the metal gate structure has a first portion vertically between the channel layers, a second portion vertically between the dielectric layer and a topmost one of the channel layers, and a third portion over the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an integrated circuit device, comprising:
depositing an epitaxial stack over a semiconductor substrate, wherein the epitaxial stack comprises a plurality of first and second semiconductor layers alternatively arranged over the semiconductor substrate and a third semiconductor layer over the first and second semiconductor layers;
patterning the epitaxial stack to form a semiconductor fin;
forming a dummy gate structure over the semiconductor fin;
replacing the third semiconductor layer in the semiconductor fin with a dielectric layer; and
replacing the dummy gate structure and first semiconductor layers in the semiconductor fin with a metal gate structure.

2. The method of claim 1, wherein a germanium concentration of the third semiconductor layer is greater than a germanium concentration of the first semiconductor layers, and the germanium concentration of the first semiconductor layers is greater than a germanium concentration of the second semiconductor layers.

3. The method of claim 1, further comprising:
etching a source/drain recess in the semiconductor fin prior to replacing the third semiconductor layer in the semiconductor fin with the dielectric layer; and
forming a source/drain epitaxial structure in the source/drain recess after replacing the third semiconductor layer in the semiconductor fin with the dielectric layer.

4. The method of claim 3, wherein a top surface of the source/drain epitaxial structure is lower than a top surface of the dielectric layer and above a top surface of a topmost one of the second semiconductor layers.

5. The method of claim 1, further comprising:
forming a plurality of inner spacers on opposite sides of the first semiconductor layers after replacing the third semiconductor layer in the semiconductor fin with the dielectric layer.

6. The method of claim 1, wherein the metal gate structure wraps the dielectric layer and the second semiconductor layers.

7. The method of claim 1, wherein replacing the third semiconductor layer in the semiconductor fin with the dielectric layer comprises:
etching the third semiconductor layer to leave an opening between the dummy gate structure and a topmost one of the first semiconductor layers; and
depositing a dielectric material into the opening between the dummy gate structure and a topmost one of the first semiconductor layers.

8. The method of claim 1, wherein a thickness of the third semiconductor layer is different from a thickness of the first semiconductor layers.

9. A method for manufacturing an integrated circuit device, comprising:
depositing an epitaxial stack over a semiconductor substrate, wherein the epitaxial stack comprises a first semiconductor layer, a second semiconductor layer over the first semiconductor layer, a third semiconductor layer over the second semiconductor layer, and a fourth semiconductor layer over the third semiconductor layer;
patterning the epitaxial stack to form a semiconductor fin;
forming a dummy gate structure over the semiconductor fin;
etching a source/drain recess in the semiconductor fin to expose sidewalls of the first to fourth semiconductor layers in the semiconductor fin;
etching away the fourth semiconductor layer to leave an opening between the dummy gate structure and the third semiconductor layer;
forming a dielectric layer in the opening between the dummy gate structure and the third semiconductor layer; and
forming a source/drain epitaxial structure in the source/drain recess after forming the dielectric layer.

10. The method of claim 9, further comprising:
laterally recessing the sidewalls of the first and third semiconductor layers after forming the dielectric layer; and
forming a plurality of inner spacers on the recessed sidewalls of the first and third semiconductor layers.

11. The method of claim 9, wherein forming the dielectric layer is performed such that the sidewalls of the first to third semiconductor layers are exposed in the source/drain recess.

12. The method of claim 9, wherein the dummy gate structure comprises a dummy gate dielectric layer and a dummy gate electrode, and a top surface of the dielectric layer is in contact with the dummy gate dielectric layer.

13. The method of claim 9, wherein a bottom surface of the dielectric layer is in contact with the third semiconductor layer.

14. The method of claim 9, further comprising:
removing the dummy gate structure to expose the dielectric layer and the first to fourth semiconductor layers in the semiconductor fin; and
replacing the first and third semiconductor layers with a metal gate structure.

15. An integrated circuit device, comprising:
a plurality of channel layers vertically spaced apart from each other;
a dielectric layer above and spaced apart from the channel layers; and
a metal gate structure surrounding the channel layers and the dielectric layer, wherein the metal gate structure has a first portion vertically between the channel layers, a second portion vertically between the dielectric layer and a topmost one of the channel layers, and a third portion over the dielectric layer.

16. The integrated circuit device of claim 15, wherein a bottom surface of the dielectric layer is in contact with the second portion of the metal gate structure, and a top surface of the dielectric layer is in contact with the third portion of the metal gate structure.

17. The integrated circuit device of claim 15, further comprising:
a plurality of gate spacers on opposite sides of the third portion of the metal gate structure, wherein the gate spacers are in contact with the dielectric layer.

18. The integrated circuit device of claim 15, wherein the metal gate structure comprises an interfacial dielectric layer in contact with the channel layers and a high-k dielectric layer over the interfacial dielectric layer and in contact with the dielectric layer.

19. The integrated circuit device of claim 15, wherein a width of the third portion of the metal gate structure is less than a width of the first portion of the metal gate structure.

20. The integrated circuit device of claim 15, further comprising:
a gate isolation structure in the metal gate structure;
a first dielectric element between the gate isolation structure and the dielectric layer; and
a plurality of second dielectric elements between the gate isolation structure and the channel layers.
